(19) United States
(12) Patent Application Publication
(10) Pub. No.: US 2007/0273416 A1
(43) Pub. Date: Nov. 29, 2007

(54) Signal delay loop and method for locking a signal delay loop

(76) Inventor: Patrick Heyne, Munchen (DE)

Correspondence Address: JENKINS, WILSON, TAYLOR & HUNT, P. A., 3100 TOWER BLVD., Suite 1200, DURHAM, NC, 27707, US

(21) Appl. No.: 11/805,899

(22) Filed: May 25, 2007

(30) Foreign Application Priority Data
May 29, 2006 (DE) 102006024960.7

(51) Int. Cl. H03L 7/06

(52) U.S. Cl. 327/158

(57) ABSTRACT

A signal delay loop (1) having a first signal delay line (4) which has a plurality of series-connectable signal delay elements with a respective associated component signal delay time (ΔT_{VE}), where the first signal delay line (4) outputs an input signal, applied to a signal input (2) of the signal delay loop (1), with a time delay to a signal output (3) of the signal delay loop (1); a second signal delay line (5) which feeds back the signal which is output on the signal output (3) of the signal delay loop (1) to a phase detector (6) which detects a phase difference (Δφ) between the feedback signal and the input signal; a control unit (7) which takes the detected phase difference (Δφ) as a basis for connecting a portion of the signal delay elements in the first signal delay line (4) in series to set a total signal delay time for the first signal delay line (4); where the respective component signal delay time (ΔT_{VE}) of each signal delay element in the first signal delay line (4) is adjustable.

The invention relates to a signal delay loop, particularly a signal delay loop for signal edge synchronization when reading data from a data store, and to a method for locking a signal delay loop of this kind.

A signal delay loop or DLL (Delay Locked Loop) circuit is a circuit for stabilizing the phase synchronism of two signals. DLL circuits have many uses, for example in the case of multiphase clock signal generators and frequency synthesizers. DLL circuits are also used to compensate for time delays between an external clock signal and an internal clock signal. DLL circuits are less sensitive toward noise than PLL (Phase Locked Loop) circuits. DLL circuits are therefore frequently used in DRAM circuits at double transmission rate (DDR-DRAM). DLL circuits may be of analog or digital design.

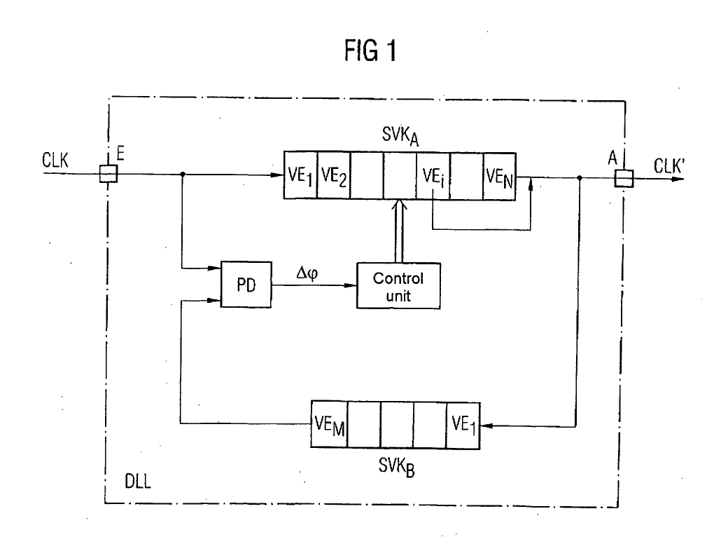

FIG. 1 shows a conventional DLL circuit. The DLL circuit has a signal input E for applying a periodic input signal which is output by a first signal delay line SVK_{A} after a time delay at an output A of the DLL circuit. The first signal delay line SVK_{A} is in the forward signal path of the DLL circuit. The signal is tapped off at the output A of the DLL circuit and is fed back via a second signal delay line SVK_{B}. A phase detector PD ascertains the phase difference between the input signal and the feedback signal. On the basis of the phase difference Δφ ascertained by the phase detector PD, a control unit connects delay elements VE in the first signal delay line SVK_{A} into the forward signal path or disconnects them from the forward signal path. The signal delay time of the first signal delay line SVK_{A} can therefore be set by the control unit. The total signal delay time of the signal through the first signal delay line SVK_{A} is obtained from the sum of the component signal delay times of all series-connected signal delay elements VE. The control loop regulates the phase difference Δφ between the input signal and the feedback signal to zero. Both the first signal delay line SVK_{A} in the forward signal path and the second signal delay line SVK_{B} in the feedback signal path in a conventional DLL circuit comprise signal delay elements which each have a constant signal delay time or component signal delay time. Altering the number of series-connected signal delay elements determines the total signal delay time of a signal delay line in such conventional DLL circuits.

The DLL circuit shown in FIG. 1 has a first signal delay line SVK_{A}, which comprises N delay elements VE, and a second signal delay line SVK_{B}, which comprises M signal delay elements.

For the signal delay time of the first signal delay line, the following is true:

ΔT_{SVK}_{_{A}}=K·ΔT_{VE},

where ΔT_{VE} is the signal delay time of a signal delay element VE and

### K is the number of delay elements VE connected in series by the control unit within the signal delay line SVK_{A} (K≦N).

If the signal frequency of the input signal f_{CLK} is low and thus the clock period T_{CLK} of the input signal CLK is long, the number K of connected delay elements VE is accordingly high.

The maximum signal delay time which can be produced by the signal delay line SVK_{A} is:

ΔT_{SVK}_{_{A}}_{=N·ΔT}_{VE}.

At a low clock frequency f_{CLK}, the number N of signal delay elements provided within the first signal delay line needs to be large enough for the DLL circuit to be able to operate even at a relatively low bottom limit frequency for the applied clock signal CLK. The component signal delay time of the individual signal delay elements ΔT_{VE} cannot be increased arbitrarily, since otherwise the accuracy or the resolution of the DLL circuit is too low at high clock signal frequencies. In addition, there are technical limitations to the extent that signal delay elements VE which have a signal delay time of less than a few picoseconds cannot currently be produced. DDR2-DRAM circuits currently operate in a frequency range of between approximately 125 MHz and 533 MHz. The necessary total signal delay time of the signal delay line is therefore 8 nsec. at the bottom limit frequency of 125 MHz. If the component signal delay time of a delay element VE ΔT_{VE} is 20 psec., K=400 delay elements therefore need to be connected in series at the bottom limit frequency. If the component signal delay time ΔT_{VE} of a delay element is approximately 20 picoseconds, the necessary resolution of 1% of the clock period T can thus be achieved at the top limit frequency of 533 MHz. In order to be able to connect KSK=400 signal delay elements, the first signal delay line SVK_{A} in the DLL circuit needs to contain at least 400 signal delay elements. The circuit complexity for providing such a large number of signal delay elements VE and the complexity for the switching elements for connecting the signal delay elements is very high in this case. Normally, the signal delay elements VE each contain current sources for stabilizing the component signal delay time of the delay element. If, when the applied clock signal CLK has a low frequency, a very large number of signal delay elements are connected in series and hence the number of active signal delay elements VE increases, the power consumption of the DLL circuit shown in FIG. 1 rises sharply. The power consumption of the conventional DLL circuit is thus firstly very high at low frequencies of the applied periodic input signal CLK and, in addition, fluctuates largely on the basis of the signal frequency of the applied clock signal. The high number of signal delay elements VE to be provided also means that the chip area required when the DLL circuit is integrated in an integrated circuit is very large.

It is therefore an object of the invention to provide a signal delay loop and a method for locking a signal delay loop which firstly permits a large frequency range for the applied input signal and secondly allows a signal delay loop to be implemented with minimum circuit complexity.

The invention achieves this object by means of a signal delay loop having the features specified in patent claim 1.

The invention provides a signal delay loop having
a first signal delay line which has a plurality of series-connectable signal delay elements with a respective associated component signal delay time, where the first signal delay line outputs an input signal, applied to a signal input of the signal delay loop, with a time delay to a signal output of the signal delay loop;
a second signal delay line which feeds back the signal which is output on the signal output of the signal delay loop to a phase detector which detects a phase difference between the feedback signal and the input signal;
a control unit which takes the detected phase difference as a basis for connecting a portion of the signal delay elements in the first signal delay line in series to set a total signal delay time for the first signal delay line;
where the respective component signal delay time of each signal delay element in the first signal delay line is adjustable.

The invention also provides a method for locking a signal delay loop based on the invention, where first of all the signal delay elements in the first signal delay line are connected in steps so long as the detected phase difference between the input signal and the feedback signal is greater than zero and until one of the last signal delay elements in the first signal delay line is reached, the component signal delay times of all the signal delay elements in the first signal delay line subsequently being increased and then the signal delay elements in the first signal delay line being disconnected again in steps until the detected phase difference between the input signal and the feedback signal becomes greater than zero.

The invention also provides a method for locking a signal delay loop based on the invention, in which first of all the signal delay elements in the first signal delay line are connected in steps so long as the detected phase difference between the input signal and the feedback signal is greater than zero and until one of the last signal delay elements in the first signal delay line is reached, the component signal delay time of the signal delay element reached subsequently being increased.

Embodiments of the inventive signal delay loop and embodiments of the inventive method for locking a signal delay loop of this kind are described below to explain features which are fundamental to the invention with reference to the appended figures, in which:

FIG. 1 shows a conventional DLL circuit;

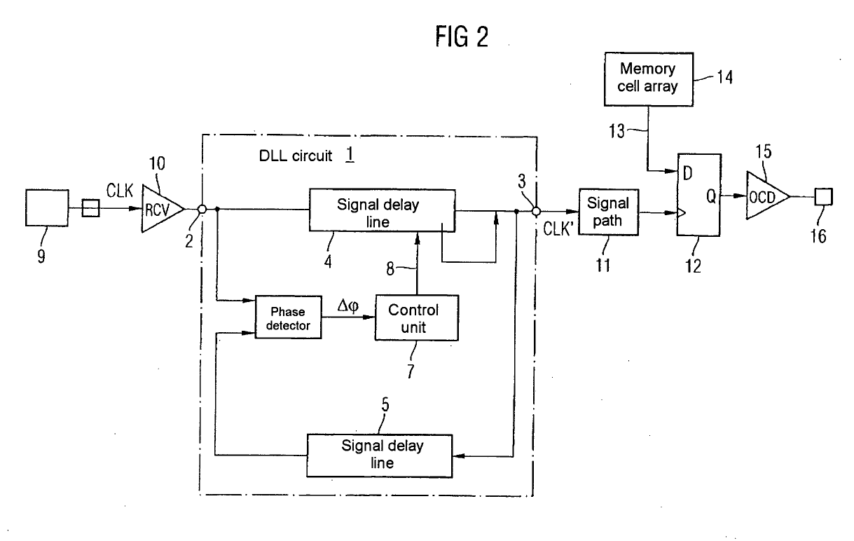

FIG. 2 shows the connection of an embodiment of the inventive DLL circuit in a signal path for reading data from a memory cell array in a DRAM store;

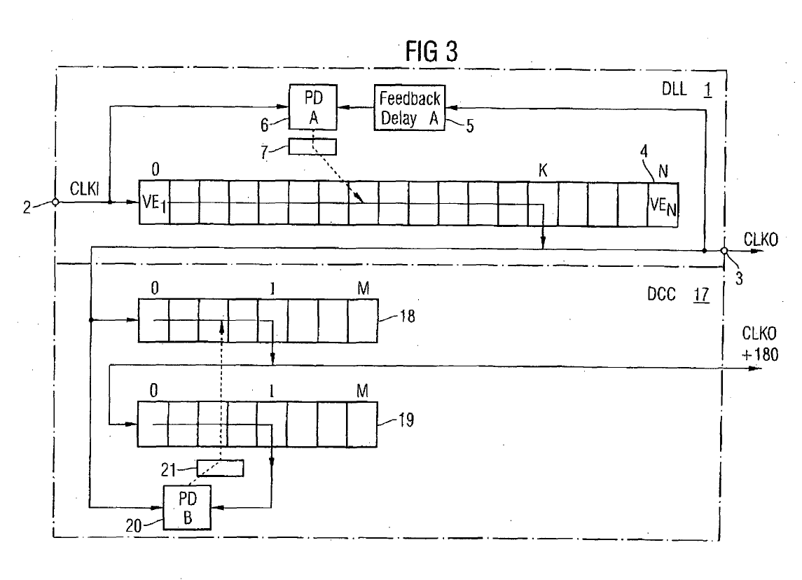

FIG. 3 shows the connection of an embodiment of the inventive DLL circuit to a duty cycle correction circuit (DCC);

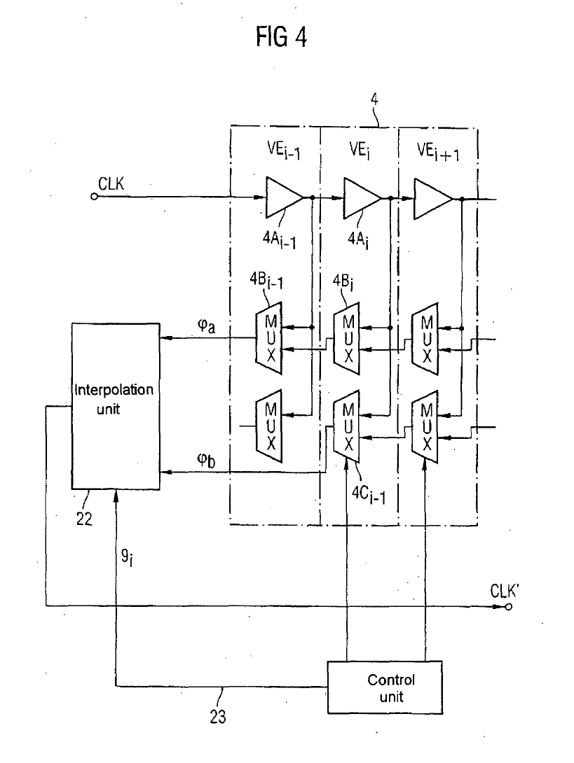

FIG. 4 shows the connection of signal delay elements in one possible embodiment of the inventive signal delay loop;

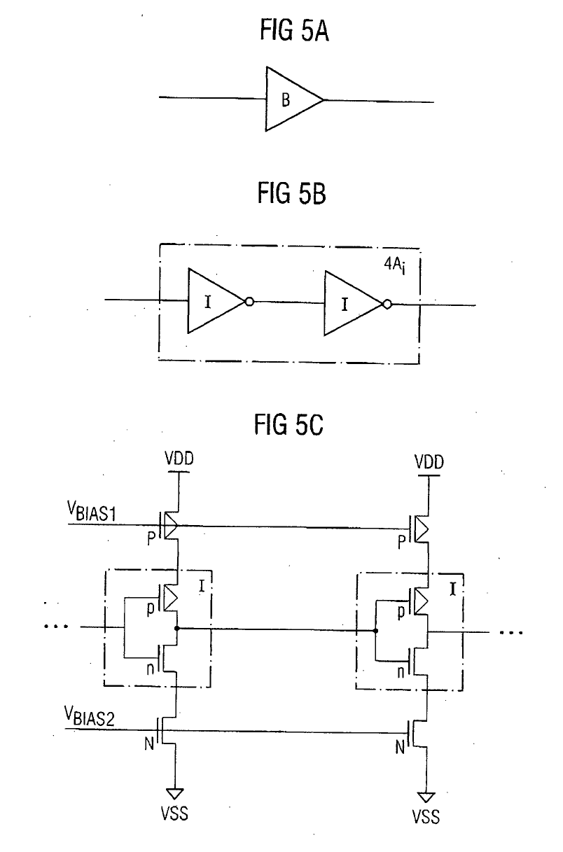

FIGS. 5a, 5b, 5c show the circuit design of signal delay elements in one possible embodiment of the inventive signal delay loop;

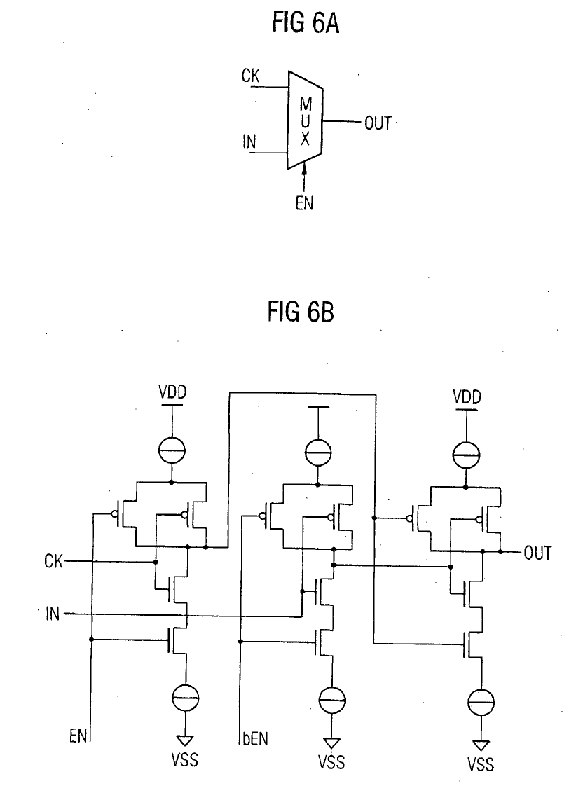

FIGS. 6a, 6b, 6c show the circuit design of multiplexers within signal delay elements in one possible embodiment of the inventive signal delay loop;

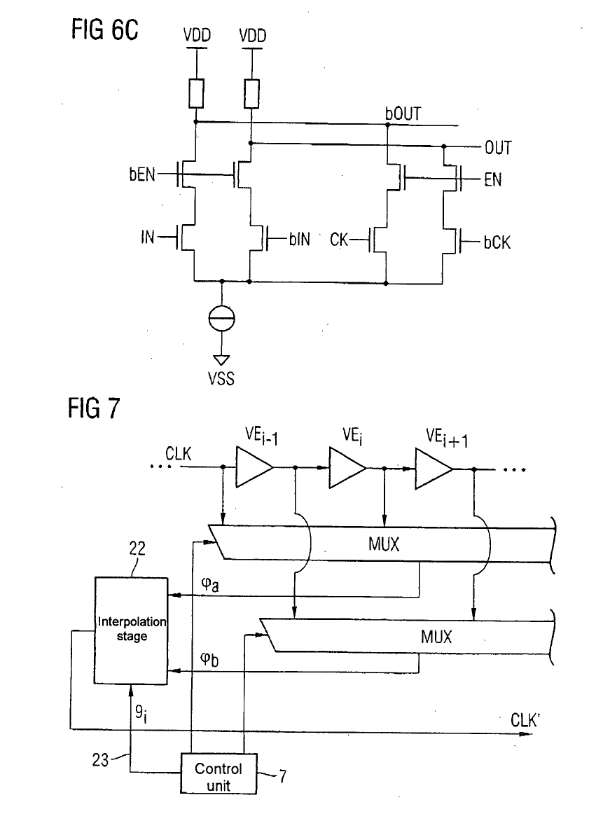

FIG. 7 shows an alternative connection for multiplexers in one possible embodiment of the inventive signal delay loop;

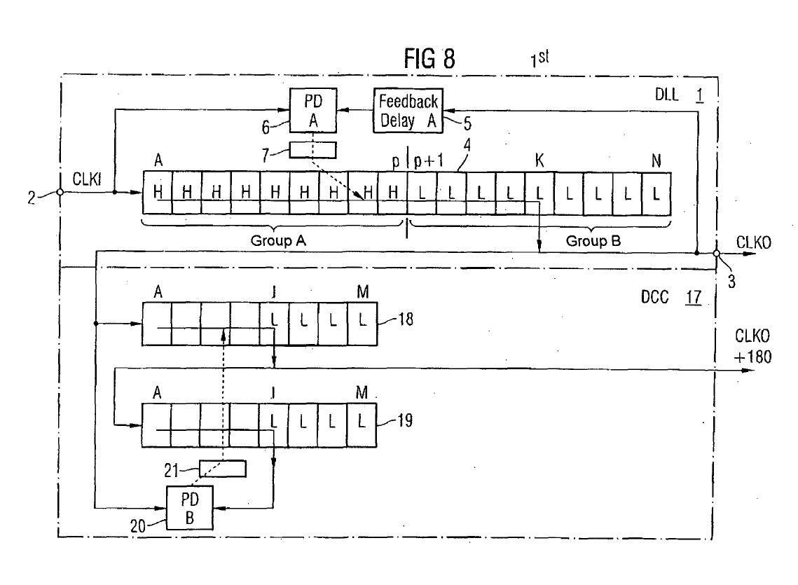

FIG. 8 shows a diagram to explain a first embodiment of a method for locking a signal delay loop based on the invention;

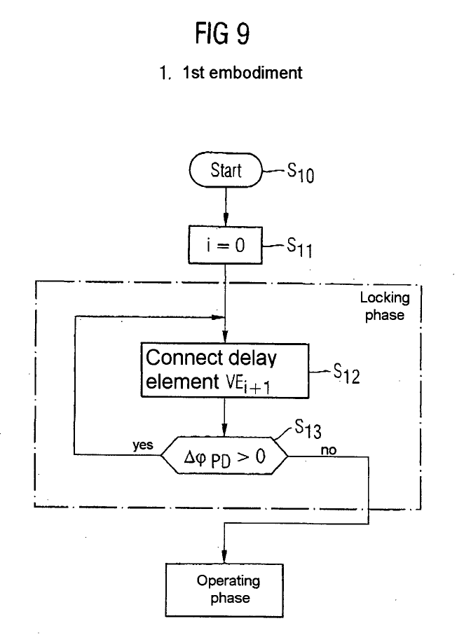

FIG. 9 shows a flowchart to explain the first embodiment of a method for locking a signal delay loop based on the invention;

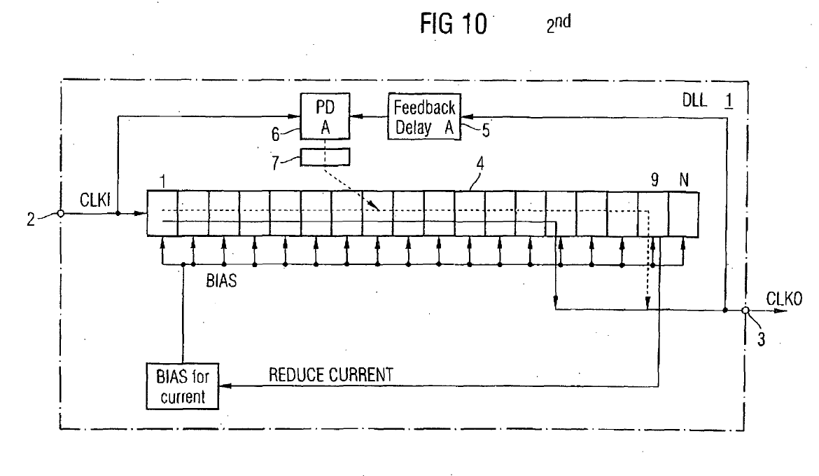

FIG. 10 shows a diagram to explain a second embodiment for locking the inventive signal delay loop;

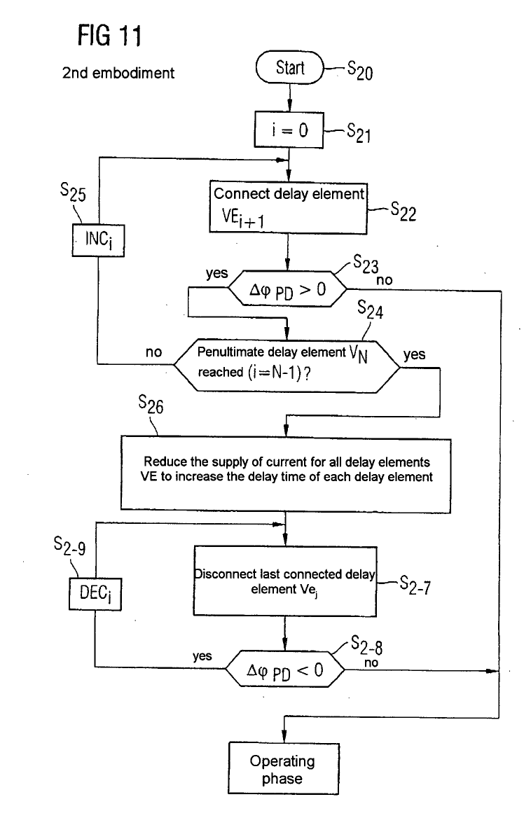

FIG. 11 shows a flowchart to illustrate the second embodiment of a method for locking the inventive signal delay loop;

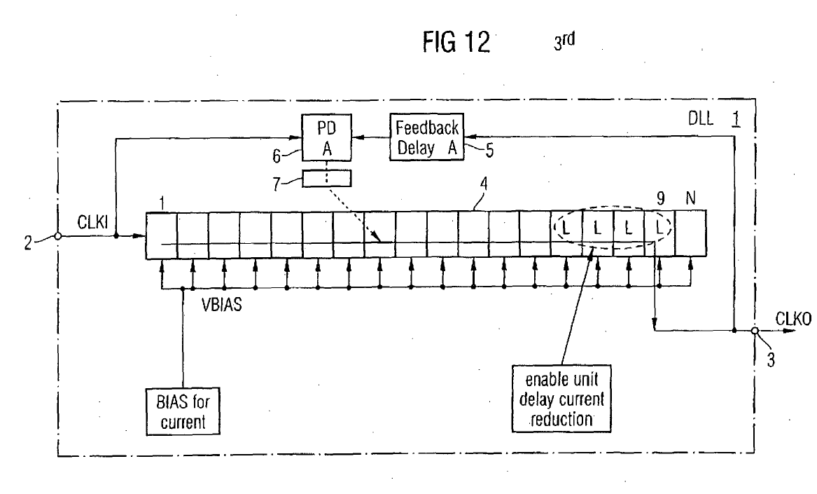

FIG. 12 shows a diagram to explain a third embodiment of the inventive method for locking a signal delay loop based on the invention;

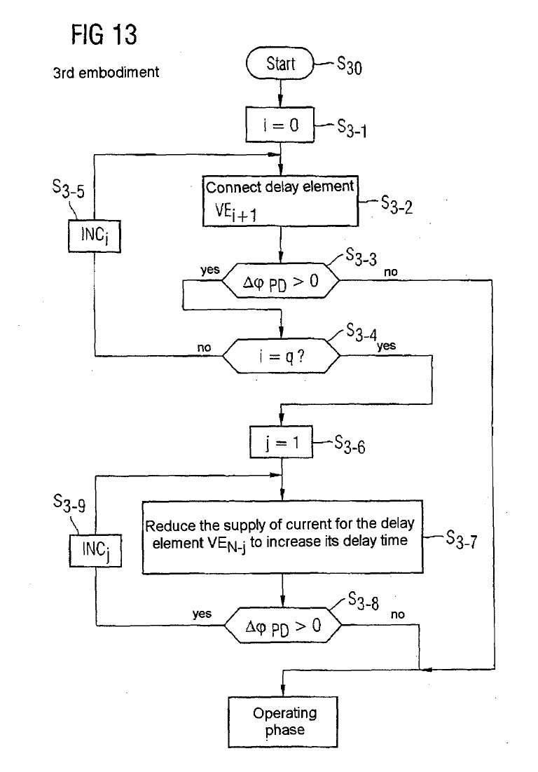

FIG. 13 shows a flowchart to illustrate the third embodiment of the method for locking the inventive signal delay loop;

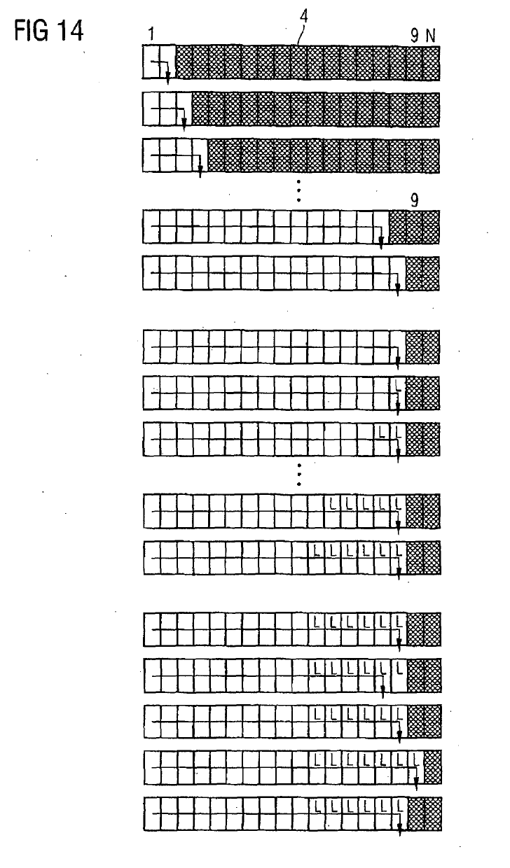

FIG. 14 shows a further diagram to explain the third embodiment of the method for locking the inventive signal delay loop.

As can be seen from FIG. 2, the signal delay loop 1 or DLL (Delay Locked Loop) circuit 1 based on one embodiment has a signal input 2 for applying a periodic input signal, for example a clock signal CLK, and a signal output 3 for outputting a time-delayed periodic output signal, for example a time-delayed clock signal CLK′. The signal delay loop 1 contains a first signal delay line 4 which comprises a plurality of series-connectable signal delay elements. The first signal delay line 4 is in a forward signal path of the signal delay loop 1 between the signal input 2 and the signal output 3 of the signal delay loop. The first signal delay line 4 outputs the periodic input signal applied to the signal input 2 to the signal output 3 after a time delay. Each of the series-connectable signal delay elements within the first signal delay line 4 has an associated component signal delay time.

Besides the first signal delay line 4, the signal delay loop 1 contains a second signal delay line 5 which is in a feedback signal path in the signal delay loop 1. The second signal delay line 5 feeds back the signal which is output on the signal output 3 to a phase detector 6. The latter detects the phase difference between the periodic input signal applied to the signal input 2 and the feedback time-delayed output signal. The phase detector 6 outputs the detected phase difference Δφ to a downstream control unit 7 in the signal delay loop 1. The control unit 7 takes the detected phase difference Δφ as a basis for connecting a portion of the signal delay elements in the first signal delay line 4 in series with one another in order to set a total signal delay time for the first signal delay line 4. The signal delay line 4 comprises N provided signal delay elements. Of these N signal delay elements, the control unit 7 connects k signal delay elements in series. To this end, the control unit 7 uses control lines 8 to actuate multiplexers within the signal delay line 4.

One advantage of the inventive signal delay loop is that the power consumption is at a minimum, particularly at low frequencies of the input signal, which is a clock signal, for example.

Another advantage of the inventive signal delay loop is that as the frequency of the input signal rises the resolution of the signal delay loop does not decrease.

FIG. 2 shows one possible use for an embodiment of the inventive signal delay loop 1 for clock edge synchronization when reading data from a memory cell array in a DRAM store. An external or internal clock signal generator 9 generates a clock signal CLK which is applied via an amplifier or receiver 10 to the signal input 2 of the inventive signal delay loop 1. The receiver or buffer 10 is used for signal amplification or for signal level shifting, for example. The delayed clock signal CLK′ which is output by the signal delay loop 1 is routed via a clock signal path 11 to the clock input of a D-type flipflop 12. The data input D of the D-type flipflop is connected to a data line 13 via which it is possible to read a data item from a memory cell array 14. The data line 13 is used to read the data item or the data bit from the memory cell array. The data bit which is read is output by a signal driver or off-chip driver 15 via a data path 16. The data signal may be a data strobe signal (DQS), for example.

The signal delay time of the second signal delay line 5 in the feedback signal path is constant in one preferred embodiment. The signal delay time of the first signal delay line 4 is obtained from the difference between the clock period of the clock signal CLK and the signal delay time which is made up of the signal delay times of the reception stage 10 in the signal path 11 and of the off-chip driver 15. The signal delay line 4 thus equalizes the signal delay through the total signal path and thus shifts the next rising signal edge of the data signal onto the signal edge of the clock signal or synchronizes the two signal edges to one another.

FIG. 3 schematically shows the connection of an embodiment of the inventive signal delay loop 1 to a duty cycle correction circuit 17 (DCC: Duty Cycle Correction). In this case, the output signal from the signal delay loop 1 forms the input signal for the duty cycle correction circuit 17. As indicated in FIG. 3, the signal delay line 4 within the signal delay loop 1 comprises N signal delay elements VE, with k signal delay elements being connected in series by the control unit 7 using multiplexers. The phase detector 6 detects the phase difference Δφ between the periodic input signal at the signal input 2 and the output signal which is fed back via the second signal delay line 5. The control loop regulates the phase difference Δφ between these two signals to zero. On the basis of the detected phase difference Δφ, the control unit 7 switches the first signal delay line 4 such that the phase difference Δφ is at a minimum. The input clock signal CLK whose timing has been delayed in this manner is output as clock signal CLK0 for the rising signal edge of a strobe data signal. As indicated in FIG. 3, the control unit 7 activates only k signal delay elements VE. The remaining signal delay elements VE in the first signal delay line 4 are deactivated or off and therefore do not consume any power either.

The duty cycle correction circuit 17 connected downstream of the signal delay loop 1 contains two signal delay lines 18, 19 of identical design which each contain M signal delay elements VE. A phase detector 20 contained in the duty cycle correction circuit 17 ascertains the phase difference Δφ′ between the clock signal CLK0 and the signal delayed by the two signal delay lines 18, 19. On the basis of the detected phase difference Δφ′, a control unit 21 contained in the duty cycle correction circuit 17 switches signal delay elements within the signal delay lines 18, 19. The arrangement of two identical signal delay lines 18, 19 with the same setting or the same number of signal delay elements which are on produces a signal whose timing is delayed by 180° relative to the clock signal CLK0 and which is output by the duty cycle correction circuit 17 for the falling signal edge of a strobe signal, for example.

FIG. 4 shows one possible connection for signal delay elements within the first signal delay line 4 in the inventive signal delay loop 1. Each signal delay element 4-i has a buffer 4Aᵢ, a first multiplexer 4Bᵢ and a second multiplexer 4Cᵢ, respectively. The multiplexers 4Bᵢ, 4Cᵢ are switched by the control unit 7. The buffer 4Aᵢ in a signal delay element 4-i in the first signal delay line 4 comprises two series-connected inverters, for example.

In one embodiment of the inventive signal delay loop 1, the outputs of the multiplexers 4B, 4C in a signal delay element can be connected to a downstream interpolation unit 22 for fine adjustment of the signal delay or signal phase. On the basis of the output signals from the two multiplexers which are on and on the basis of adjustable interpolation weighting factors gᵢ, the interpolation unit 22 produces an interpolated output signal CLK′. In one possible embodiment, the interpolation weighting factors gᵢ are set by the control unit 7 via setting lines 23.

FIG. 4 shows three signal delay elements 4-i in the first signal delay line 4. Appropriate switching of the multiplexers allows the input signal CLK to pass through the two buffers 4Aᵢ₋₁, 4Aᵢ in the two first signal delay elements 4-(i−1), 4ᵢ, for example, and then to pass firstly through the two multiplexers 4Bᵢ, 4Bᵢ₋₁ to produce an output signal with phase φₐ and secondly only through the bottom multiplexer 4Cᵢ in the delay element 4-i to produce an output signal with phase Pb. The two signals applied to the interpolation unit 22 differ in this example by the signal delay time of a multiplexer. The interpolation unit 22 then interpolates between the signal with phase φₐ and the signal with phase Pb to produce an interpolated output signal CLK′. The interpolation unit 22 is used for fine adjustment and to improve the phase resolution.

FIGS. 5a, 5b, 5c show one possible circuit implementation for the buffers 4Aᵢ within a signal delay element 4-i in the first signal delay line 4. Each buffer 4Aᵢ in a signal delay element 4-i preferably comprises at least two series-connected inverters, as illustrated in FIG. 5b.

These two inverters are preferably formed by two complementary field effect transistors, namely a P-FET and an N-FET, as shown in FIG. 5c. The component signal delay time through a buffer or a signal delay element 4-i is set by means of current sources in the implementation shown in FIG. 5c. These current sources are firstly formed by P-type field effect transistors whose gate is connected to a first BIAS voltage VBIAS1 and are formed by N-type field effect transistors whose gate is connected to a second BIAS voltage VBIAS2. The better the current supply to the inverter stages, the shorter the signal delay times of the inverter stages. By setting the BIAS voltages VBIAS1, VBIAS2, it is therefore possible to set a component signal delay time for a buffer 4Aᵢ within a signal delay element 4 individually.

FIGS. 6a, 6b, 6c show possible implementations of the multiplexers 4B, 4C contained in the signal delay elements 4-i in the first signal delay line 4.

FIG. 6b shows one possible implementation using CMOS technology with three appropriately connected NAND gates.

FIG. 6c shows one possible circuit implementation of the multiplexers using CML (Current Mode Logic) technology. In this case, the switching control signal or an enable signal EN is applied to the multiplexer by the control unit 7.

FIG. 7 shows an alternative embodiment for the connection of the signal delay element in the first signal delay line 4. In this case, the multiplexers are not integrated in the signal delay elements but rather form independent components.

FIG. 8 illustrates the locking or lock-in process in a first embodiment of a method based on the invention in the inventive signal delay loop or DLL circuit 1. As can be seen from FIG. 8, the N signal delay elements 4-i in the first signal delay line 4 are divided into two groups. The first P signal delay elements have a high supply of current (H: High) and therefore have a correspondingly short signal delay time. The remaining N-P signal delay elements are supplied with a small supply current (L: Low) and have a correspondingly longer signal delay time. The lower the signal frequency of the clock signal CLK applied to the signal input 2, the more signal delay elements in the first signal delay line 4 are connected by the control unit 7. In the example shown in FIG. 8, k signal delay elements are connected. The different signal delay times of the signal delay elements 4-i within the first signal delay line 4 can be implemented by appropriate current settings in one embodiment. In an alternative embodiment, the signal delay elements in the two groups have different circuit designs, for example in terms of the ratio of channel width and channel length for the field effect transistors contained therein. The component signal delay times of the P signal delay elements within the first group have a respective low setting, and the component signal delay times of the remaining signal delay elements in the signal delay line 4 have a respective high setting. The settings of the signal delay times have been preset statically in the embodiment shown in FIG. 8. The interpolation unit 22 connected downstream of the signal delay line 4 is not shown in FIG. 8. At high clock signal frequencies for the input signal, the control unit 7 effects control only between signal delay elements in the first group (group A), which each have a low signal delay time. The phase resolution of the inventive signal delay loop 1 is therefore accordingly high at high clock signal frequencies. At low clock signal frequencies, the control unit 7 effects control between delay elements in the second group (group B) within the signal delay line 4. At low clock signal frequencies, the resolution of the signal delay is therefore admittedly lower, but this is not critical.

In the embodiment shown in FIG. 8, the signal delay line is in two groups (group A, group B) divided into different component signal delay times. In further embodiments, further graduation in a plurality of groups with a plurality of degrees for the component signal delay time or the current limiting is also possible. In this case, the signal delay elements belonging to groups which are situated closer to the signal input 2 of the DLL circuit 1 each have a short component signal delay time, while the signal delay elements within groups situated further away from the signal input 2 have a longer signal delay time. The division of the component signal delay times of the signal delay elements into degrees makes it possible firstly to provide the demanded resolution for the signal delay or for the signal phase at high frequencies and secondly to minimize the number of signal delay elements which need to be connected at low clock frequencies, so that the power consumption of the inventive signal delay loop 1 is at a minimum overall.

FIG. 9 shows a flowchart for a first embodiment of a method based on the invention for locking the inventive signal delay loop 1 in the case of the example of a signal delay loop 1 which is shown in FIG. 8.

After a starting step S₁₀, a counter i for counting the signal delay elements which are on in the first signal delay line 4 is initialized to zero in a step S1-1. In a locking phase, the control circuit 7 connects the next signal delay element within the signal delay line 4 in a step S12 until it is established in a step S13 that the phase difference Δφ between the input signal CLK and the feedback signal is less than zero.

FIG. 10 schematically shows a further embodiment of the inventive method for locking a signal delay loop 1 based on the invention. In this embodiment, the component signal delay time or the signal delay of each signal delay element within the signal delay line 4 is first of all set to be the same. The control unit 7 then connects further signal delay elements in the first signal delay line 4 in steps. This is done so long as the detected phase difference Δφ between the input signal CLK and the signal which is fed back via the second signal delay line 5 is greater than zero and until one of the last signal delay elements within the signal delay line 4 is reached. This signal delay element is the penultimate signal delay element in the signal delay line 4, for example, as shown in FIG. 10. As soon as the control unit 7 reaches this penultimate signal delay element q within the signal delay line 4, the component signal delay time of all the signal delay elements within the first signal delay line 4 is increased. This is done, by way of example, by virtue of the BIAS voltage from current sources within the signal delay elements being reduced. In this context, controllable current sources within the signal delay elements are actuated such that they supply the inverter stages contained in the signal delay elements with less current, so that the component signal delay time of each signal delay element is increased. This first of all produces a noticeable sudden phase change or an abrupt increase in the total signal delay time of the signal delay line 4. In a first embodiment, the control unit 7 therefore subsequently disconnects preceding signal delay elements, starting from the signal delay element q reached, again until the detected phase difference Δφ between the input signal and the feedback signal is greater than zero and the desired operating point is thus reached. An alternative option is for the increase in the component signal delay time of all the signal delay elements to be followed by switching back to the first signal delay element in the signal delay line 4 and then connecting the signal delay elements in steps until either one of the last signal delay elements q in the signal delay line 4 is reached again or the detected phase difference Δφ becomes less than zero. Another option is for the number of supply elements which are on to be abruptly reduced at the same time as the change in the BIAS voltage. In the case of the embodiment shown in FIG. 10 for locking the signal delay loop 1, the component signal delay times of the individual signal delay elements are switched over.

FIG. 11 shows a flowchart to illustrate a possible method for locking the signal delay loop 1. After a starting step S₂₀, the count variable i or the pointer is first of all initialized to zero by the control unit 7 in a step S₂₁.

In a step S₂₂, the control unit 7 connects the next signal delay element in the signal delay line 4 until it is recognized, in the a step S₂₃, that the phase difference Δφ between the input signal and the feedback signal is less than zero. So long as the phase difference is greater than zero, a check is performed in a step S₃₄ to determine whether or not the q-th, for example the penultimate, signal delay element within the signal delay line 4 has been reached. If the penultimate signal delay element has not yet been reached, the pointer or the counter i is incremented in a step S₂₅ and the process returns to step S₂₂. If the penultimate signal delay element has been reached, the component signal delay times of all the delay elements within the signal delay line 4 are increased simultaneously to increase the total delay time, for example by reducing the respective supply of current by reducing the BIAS voltage. The reduction in the supply of current or the increase in the component signal delay time of each signal delay element is effected in step S₂₆. To compensate for the relatively large sudden phase change which occurs in the process, the signal delay element connected last is subsequently disconnected again in a step S₂₇ until a change of arithmetic sign is established for the phase difference in a step S₂₈. So long as no change of arithmetic sign is established, the counter i is decremented in a step S₂₉. When a change of arithmetic sign occurs, the locking or lock-in phase has ended and the signal delay loop 1 changes to the operating phase, for example in order to be able to react to temperature changes in the chip.

FIG. 12 schematically shows the locking process based on a further embodiment of the inventive method. This locking process likewise first of all involves signal delay elements in the first signal delay line being connected by the control unit 7 so long as the detected phase difference Δφ between the input signal and the feedback signal is greater than zero and until one of the last signal delay elements, namely the q-th signal delay element, has been reached. Next, not the component signal delay time of all the signal delay elements but rather first of all only the component signal delay time of the signal delay element which has been reached is increased. By way of example, this is done by reducing the supply of current to this signal delay element. Next, the signal delay elements connected upstream of the q-th signal delay element are switched over to the low current mode in steps. That is to say that first of all the q−1-th signal delay element is switched over to the low current mode to increase the component signal delay time and then the q−2-th signal delay element etc. This is done until it is established that the detected phase difference Δφ between the input signal and the feedback signal becomes less than zero and hence the operating point has been reached.

FIG. 13 shows a flowchart of a possible embodiment for locking the signal delay loop 1. After a step S₃₀, the counter for the signal delay elements is first of all initialized to zero by the control circuit 7 in a step S31.

Next, the next signal delay element is connected by the control circuit 7 in a step S₃₂ until it is established in step S₃₃ that the phase difference Δφ between the input signal and the feedback signal is negative or a change of arithmetic sign has taken place. So long as the phase difference Δφ is positive, a check is performed in a step S₃₄ to determine whether or not the penultimate signal delay element q has already been reached. So long as this is not the case, the counter i is incremented in a step S₃₅ and then the next signal delay element is connected in steps or iteratively in a step S₃₂. If it is identified in step S₃₄ that the penultimate signal delay element has been reached, a further counter is initialized in a step S36 and then in a step S₃₇ the supply of current to the signal delay element connected upstream of the q-th signal delay element is reduced in order to increase its component signal delay time. So long as no change of arithmetic sign is established in step S38 for the phase difference Δφ between the input signal and the feedback signal, the second counter i is incremented in step S₃₉. As soon as a change of arithmetic sign has occurred for the phase difference, the locking phase or the lock-in phase of the signal delay loop 1 is complete and the signal delay loop changes over to the normal operating phase.

FIG. 14 schematically shows the procedure in the case of the embodiment shown in FIG. 13 for the inventive method for locking the signal delay loop 1. The shaded signal delay elements within the signal delay line 4 are the activated signal delay elements. First, the signal delay elements are connected and deactivated in steps until the penultimate signal delay element q within the signal delay line 4 has been reached. Next, the supply of current to the signal delay elements connected upstream of the penultimate signal delay element q is switched to “Low” (L) in steps, so that the respective component signal delay time of these signal delay elements is increased. Gradually, a plurality of signal delay elements are switched to the low current mode. Once the signal delay is sufficient, the currents are kept constant and the pointer or counter is activated, for example in order to react to temperature changes, as shown in the bottom part of FIG. 14.

In the case of the inventive signal delay loop 1, the power consumption is reduced on the basis of the demanded performance or frequency which is required.

1. A signal delay loop (1) having:
(a) a first signal delay line (4) which has a plurality of series-connectable signal delay elements with a respective associated component signal delay time (ΔT_{VE}),
where the first signal delay line (4) outputs an input signal, applied to a signal input (2) of the signal delay loop (1), with a time delay to a signal output (3) of the signal delay loop (1);
(b) a second signal delay line (5) which feeds back the signal which is output on the signal output (3) of the signal delay loop (1) to a phase detector (6) which detects a phase difference (Δφ) between the feedback signal and the input signal;
(c) a control unit (7) which takes the detected phase difference (Δφ) as a basis for connecting a portion of the signal delay elements in the first signal delay line (4) in series to set a total signal delay time for the first signal delay line (4);
(d) where the respective component signal delay time (ΔT_{VE}) of each signal delay element in the first signal delay line (4) is adjustable.

2. The signal delay loop as claimed in claim 1, where component signal delay times (ΔT_{VE}) of the signal delay elements in the first signal delay line (4) can be set individually by the control unit (7).

3. The signal delay loop as claimed in claim 1, where the signal delay elements in the first signal delay line (4) each have a variable component signal delay time which can be set on the basis of a BIAS voltage (VBIAS) applied to the signal delay element.

4. The signal delay loop as claimed in claim 1, where the signal delay elements in the first signal delay line (4) each contain current sources which can be actuated to set the component signal delay time of the respective signal delay element on the basis of the BIAS voltage (VBIAS).

5. The signal delay loop as claimed in claim 4, where the current sources are formed by controllable transistors.

6. The signal delay loop as claimed in claim 1, where the signal delay times of the signal delay elements in the first signal delay line (4) have been set by means of circuit design.

7. The signal delay loop as claimed in claim 1, where each signal delay element has a signal buffer which comprises at least two series-connected inverters (I).

8. The signal delay loop as claimed in claim 7, where the signal buffer is connected to multiplexers for connecting the signal delay element in series.

9. The signal delay loop as claimed in claim 8, where the multiplexers can be actuated by the control unit (7).

10. The signal delay loop as claimed in claim 9, where each signal delay element (4-i) in the first signal delay line (4) has:
a signal buffer (4Ai) for signal delay of an output signal from the upstream signal delay element (4-i−1) and
two multiplexers (4Bᵢ, 4Cᵢ) which each have a first input, which is connected to an output of the signal buffer (4Aᵢ), and a second input, which is connected to an output of a multiplexer in a signal delay element (4ᵢ₊₁) connected downstream of the signal delay element.

11. The signal delay loop as claimed in claim 10, where the outputs of the two multiplexers (4Aᵢ, 4Bᵢ) in a signal delay element can be connected to an interpolation stage (22).

12. The signal delay loop as claimed in claim 11, where the interpolation stage (22) produces an interpolated output signal from the first signal delay line (4) on the basis of the output signals from the two multiplexers and on the basis of adjustable interpolation weighting factors (9ᵢ).

13. The signal delay loop as claimed in claim 12, where the interpolation weighting factors (9ᵢ) can be set by the control unit (7).

14. The signal delay loop as claimed in claim 1, where the signal delay loop (1) is connected to a duty cycle correction circuit (17).

15. The signal delay loop as claimed in claim 1, where the signal delay elements are designed using CML (Current Mode Logic) technology.

16. The signal delay loop as claimed in claim 1, where the signal delay elements are designed using CMOS technology.

17. The signal delay loop as claimed in claim 1, where the input signal is a clock signal (CLK) which is produced by a clock signal generator (9).

18. The signal delay loop as claimed in claim 1, where the component signal delay times of signal delay elements in a first group of signal delay elements in the first signal delay line (4) are each set low, and
where the component signal delay times of signal delay elements in a second group of signal delay elements in the first signal delay line (4) are each set high.

19. A method for locking a signal delay loop as claimed in claim 18,
where the signal delay elements in the first signal delay line (4) are connected in steps by the control unit (7) until a change of arithmetic sign occurs for the detected phase difference (Δφ) between the input signal and the feedback signal.

20. A method for locking a signal delay loop as claimed in claim 1, having the following steps:
(a) signal delay elements in the first signal delay line (4) are connected in steps so long as the detected phase difference (Δφ) between the input signal and the feedback signal is greater than zero and until one of the last signal delay elements in the first signal delay line (4) is reached;
(b) the component signal delay time of all the signal delay elements in the first signal delay line (4) is increased;
(c) signal delay elements in the first signal delay line (4) are disconnected in steps until the detected phase difference (Δφ) between the input signal and the feedback signal becomes greater than zero.

21. A method for locking a signal delay loop as claimed in claim 1, having the following steps:
(a) signal delay elements in the first signal delay line (4) are connected in steps so long as the detected phase difference (Δφ) between the input signal and the feedback signal is greater than zero and until one of the last signal delay elements in the first signal delay line (4) is reached;
(b) the component signal delay time of the signal delay element reached is increased; and
(c) the respective component signal delay times of the signal delay elements connected upstream of the signal delay element reached are increased in steps until the detected phase difference (Δφ) between the input signal and the feedback signal becomes less than zero.

22. The use of the signal delay loop as claimed in one of claims 1 to 18 for signal edge synchronization when data are read from a data store.
